(19) United States
(12) Patent Application Publication
(10) Pub. No.: US 2016/0081204 A1
(43) Pub. Date: Mar. 17, 2016

(54) ELECTRONIC DEVICE INCLUDING FLEXIBLE DISPLAY ELEMENT

(71) Applicant: Samsung Electronics Co., Ltd., Suwon-si (KR)

(72) Inventors: Sang-Il PARK, Seoul (KR); Nam-Kyu KIM, Seongnam-si (KR); Tomohiro HARATA, Seoul (KR)

(21) Appl. No.: 14/848,550

(22) Filed: Sep. 9, 2015

(30) Foreign Application Priority Data
Sep. 12, 2014 (KR) 10-2014-0121392

(51) Int. Cl. H05K 5/00; H05K 5/02

(52) U.S. Cl. CPC H05K 5/0017; H05K 5/0217

(57) ABSTRACT

An electronic device is provided. The electronic device includes a main body, a flexible display mounted to be movable in a first direction on the main body, and a support unit disposed on the main body that faces a surface of the flexible display and moves in the direction on the main body. A portion of the flexible display is selectively disposed within the main body together with the support unit while moving on the main body. The electronic device as described above may be implemented according to various embodiments.

### CROSS-REFERENCE TO RELATED APPLICATION(S)

This application claims the benefit under 35 U.S.C. §119(a) of a Korean patent application filed on Sep. 12, 2014 in the Korean Intellectual Property Office and assigned Serial number 10-2014-0121392, the entire disclosure of which is hereby incorporated by reference.

### TECHNICAL FIELD

The present disclosure relates to an electronic device. More particularly, the present disclosure relates to an electronic device including a flexible display element.

### BACKGROUND

The term electronic device refers to a device that performs specific functions according to programs. Examples of such an electronic device include an electronic scheduler, a portable multimedia reproducer, a mobile communication terminal, a tablet personal computer (PC), an image/sound device, a desktop/laptop computer, a vehicular navigation system, and a home appliance. For example, such an electronic device may output information stored therein as a character, a sound, or an image. As the integration of electronic devices has increased and wireless data communication has been popularized, various functions have recently been incorporated in a single electronic device. For example, a communication function, an entertainment function such as a game, a multimedia function such as music/video image reproduction, a communication and security function, a schedule management function, and a financial function (e.g., mobile banking or an electronic wallet), are integrated in a single electronic device.

A display element integral to an electronic device outputs contents, such characters or images, to provide visual information to a user. As an entertainment function or a multimedia function of the electronic device improves, users may favor a high-definition and large-screen display element. As such, a flexible display element may be useful in utilizing a space and providing a large screen that requires a small space and may allow a screen display region to be expanded and used on the electronic device, as needed.

The above information is presented as background information only to assist with an understanding of the present disclosure. No determination has been made, and no assertion is made, as to whether any of the above might be applicable as prior art with regard to the present disclosure.

### SUMMARY

A structure capable of supporting a flexible display when the flexible display is in an extended state (e.g., when a screen display region is in the extended state on the electronic device) is not sufficient in practice. When a stable support structure is not provided, the flexible display cannot stay flat and the screen displayed to the user may be distorted.

In addition, when a touch screen function is incorporated into the flexible display element, the screen may be distorted by the user's touch.

Aspects of the present disclosure are to address at least the above-mentioned problems and/or disadvantages and to provide at least the advantages described below. Accordingly, an aspect of the present disclosure is to provide an electronic device that has a structure capable of stably supporting a flexible display.

Another aspect of the present disclosure is to provide an electronic device having a flexible display that is stably supported so that a high quality screen can be supplied to the user and usability can be improved. In accordance with an aspect of the present disclosure, an electronic device is provided. The electronic device includes a main body, a flexible display mounted to be movable in a first direction on the main body, and a support unit disposed on the main body that faces a surface of the flexible display and moves in the direction on the main body, wherein a first region of the flexible display is selectively disposed within the main body together with the support unit while moving on the main body. In accordance with another aspect of the present disclosure, an electronic device is provided. The electronic device includes a main body, a slide unit coupled to the main body and to be displaced in a movement direction, a support unit provided in an end of the slide unit to move on the main body together with the slide unit, and a flexible display fixed to the slide unit, wherein as the slide unit moves, a first portion of the flexible display is selectively disposed within the main body together with the support unit.

As the slide unit moves, a portion of the flexible display may be selectively disposed within the main body together with the support unit.

According to various embodiments of the present disclosure, since the electronic device may accommodate the flexible display in the main body, and may use the flexible display in an extended state as needed, it is possible to provide a high definition and large screen that is capable of being accommodated in a small space. In addition, by disposing the support unit in the main body, the portion of the flexible display disposed within the main body can be stably supported. By disposing the support unit to support the flexible display, deformation of the flexible display can be suppressed even if a screen is output or the user touches the flexible display. In addition, since the deformation of the flexible display is suppressed, it is possible to prevent the distortion of the screen so that a high quality screen can be provided to the user and usability can be improved.

Other aspects, advantages, and salient features of the disclosure will become apparent to those skilled in the art from the following detailed description, which, taken in conjunction with the annexed drawings, discloses various embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a view illustrating a network environment including an electronic device according to various embodiments of the present disclosure;

FIGS. 2, 3, 4, and 5 are various perspective views of an electronic device according to an embodiment of the present disclosure;

FIGS. 6, 7, and 8 are various exploded perspective views of an electronic device according to an embodiment of the present disclosure;

FIGS. 9 and 10 are various perspective views of an electronic device according to an embodiment of the present disclosure;

FIGS. 11, 12, 13, 14, and 15 are various perspective views illustrating an electronic device according to an embodiment of the present disclosure;

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the present disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the present disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the present disclosure. Accordingly, it should be apparent to those skilled in the art that the following description of various embodiments of the present disclosure is provided for illustration purpose only and not for the purpose of limiting the present disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

In the present disclosure, the expression “have”, “may have”, “include” or “may include” refers to existence of a corresponding feature (e.g., numerical value, function, operation, or components such as elements), and does not exclude existence of additional features.

As used herein, the expression “A or B”, “at least one of A and/or B”, or “one or more of A and/or B” may include any or all possible combinations of items enumerated together. For example, the expression “A or B”, “at least one of A and B”, or “at least one of A or B” refers to all of (1) including at least one A, (2) including at least one B, or (3) including all of at least one A and at least one B.

The expression “a first”, “a second”, “the first”, or “the second” used in various embodiments of the present disclosure may modify various components regardless of the order and/or the importance but does not limit the corresponding components. The above expressions are used merely for the purpose of distinguishing an element from the other elements. For example, a first user device and a second user device indicate different user devices although both of them are user devices. For example, a first element may be termed a second element, and similarly, a second element may be termed a first element without departing from the scope of the present disclosure.

It should be understood that when an element (e.g., first element) is referred to as being (operatively or communicatively) “connected,” or “coupled,” to another element (e.g., second element), it may be directly connected or coupled directly to the other element or any other element (e.g., third element) may be interposer between them. In contrast, it may be understood that when an element (e.g., first element) is referred to as being “directly connected,” or “directly coupled” to another element (second element), there are no element (e.g., third element) interposed between them.

As used herein, the expression “configured to” may be interchangeably used with the expression “suitable for”, “having the capability to”, “designed to”, “adapted to”, “made to”, or “capable of”. The term “configured to” may not necessarily imply “specifically designed to” in hardware. Alternatively, in some situations, the expression “device configured to” may mean that the device, together with other devices or components, “is able to”. For example, the phrase “processor adapted (or configured) to perform A, B, and C” may mean a dedicated processor (e.g. embedded processor) only for performing the corresponding operations or a generic-purpose processor (e.g., central processing unit (CPU) or application processor (AP)) that can perform the corresponding operations by executing one or more software programs stored in a memory device.

The terms used herein are merely for the purpose of describing particular embodiments and are not intended to limit the scope of other embodiments. As used herein, singular forms may include plural forms as well unless the context clearly indicates otherwise. Unless defined otherwise, all terms used herein, including technical terms and scientific terms, may have the same meaning as commonly understood by a person of ordinary skill in the art to which the present disclosure pertains. Such terms as those defined in a generally used dictionary are to be interpreted to have the meanings equal to the contextual meanings in the relevant field of the art, and are not to be interpreted to have ideal or excessively formal meanings unless clearly defined in the present disclosure. In some cases, even the term defined in the present disclosure should not be interpreted to exclude embodiments of the present disclosure.

For example, the electronic device may include at least one of a smartphone, a tablet personal computer (PC), a mobile phone, a video phone, an electronic book (e-book) reader, a desktop PC, a laptop PC, a netbook computer, a personal digital assistant (PDA), a portable multimedia player (PMP), an MP3 player, a mobile medical appliance, a camera, and a wearable device (e.g., a head-mounted-device (HMD) such as electronic glasses, electronic clothes, an electronic bracelet, an electronic necklace, an electronic accessory, electronic tattoos, or a smart watch).

According to some embodiments, the electronic device may be a smart home appliance. The home appliance may include at least one of, for example, a television, a digital video disk (DVD) player, an audio, a refrigerator, an air conditioner, a vacuum cleaner, an oven, a microwave oven, a washing machine, an air cleaner, a set-top box, a home automation control panel, a security control panel, a TV box (e.g., Samsung HomeSync™, Apple TV™, or Google TV™), a game console (e.g., Xbox™ and PlayStation™), an electronic dictionary, an electronic key, a camcorder, and an electronic photo frame.

According to another embodiment, the electronic device may include at least one of various medical devices (e.g., various portable medical measuring devices (a blood glucose monitoring device, a heart rate monitoring device, a blood pressure measuring device, a body temperature measuring device, etc.), a magnetic resonance angiography (MRA), a magnetic resonance imaging (MRI), a computed tomography (CT) machine, and an ultrasonic machine), a navigation device, a global positioning system (GPS) receiver, an event data recorder (EDR), a flight data recorder (FDR), a vehicle infotainment devices, an electronic devices for a ship (e.g., a navigation device for a ship, and a gyro-compass), avionics, security devices, an automotive head unit, a robot for home or industry, an automatic teller's machine (ATM) in banks, point of sales (POS) in a shop, or internet device of things (e.g., a light bulb, various sensors, electric or gas meter, a sprinkler device, a fire alarm, a thermostat, a streetlamp, a toaster, a sporting goods, a hot water tank, a heater, a boiler, etc.).

According to various embodiments, the electronic device may include at least one of a part of furniture or a building/structure, an electronic board, an electronic signature receiving device, a projector, and various kinds of measuring instruments (e.g., a water meter, an electric meter, a gas meter, and a radio wave meter). The electronic device according to various embodiments of the present disclosure may be a combination of one or more of the aforementioned various devices. The electronic device according to various embodiments of the present disclosure may be a flexible device. Further, the electronic device according to an embodiment of the present disclosure is not limited to the aforementioned devices, and may include a new electronic device according to the development of technology

Hereinafter, an electronic device according to various embodiments will be described with reference to the accompanying drawings. As used herein, the term “user” may indicate a person who uses an electronic device or a device (e.g., an artificial intelligence electronic device) that uses an electronic device.

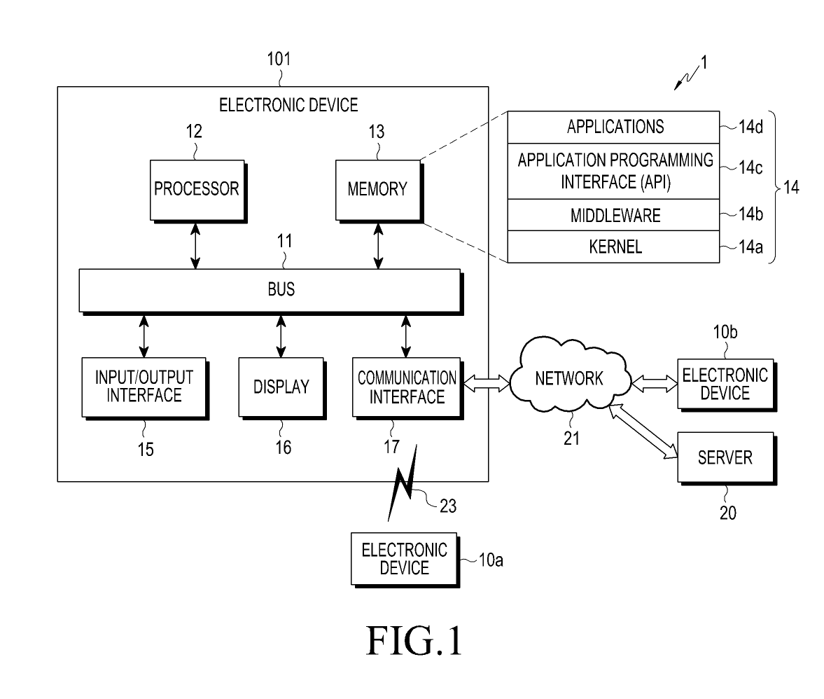

FIG. 1 is a view illustrating a network environment including an electronic device according to various embodiments of the present disclosure.

Referring to FIG. 1, descriptions will be made on an electronic device 10 within a network environment 1 in various embodiments. The electronic device 10 may include a bus 11, a processor 12, a memory 13, an input/output interface 15, a display 16, and a communication interface 17. In a certain embodiment, the electronic device 10 may omit at least one of the components or may be additionally provided with another component.

The bus 11 may include, for example, a circuit that connects the above-discussed elements 11 to 17 and transmits communication (e.g., a control message and/or data) between the components.

The processor 12 may include one or more of a CPU, an AP, and a communication processor (CP). The processor 12 may execute, for example, an arithmetic operation or data processing related to a control and/or communication of one or more other components of the electronic device 10.

The memory 13 may include a volatile memory and/or a non-volatile memory. The memory 13 may store therein, for example, commands or data related to one or more components of the electronic device 10. According to one embodiment, the memory 13 may store therein software and/or a program 14. The program 14 may include, for example, a kernel 14a, a middleware 14b, an application programming interface (API) 14c, and/or an application 14d. At least some of the kernel 14a, the middleware 14b, and the API 14c may be referred to as an operating system (OS).

The kernel 14a may control or manage, for example, system resources (e.g., the bus 11, the processor 12, or the memory 13) used for executing operations or functions implemented the other programs (e.g., the middleware 14b, the API 14c, or the application program 14d). In addition, the kernel 14a may provide an interface that allows the middleware 14b, the API 14c, or the applications 14d to access individual components of the electronic device 10 so as to control or manage the system resources.

The middleware 14b may play an intermediary role such that the API 14c or the application program 14d may communicate with the kernel 14a so as to exchange data. In addition, in connection with task requests received from the application program 14d, the middleware 14b may perform a control (e.g., scheduling or load balancing) for the task requests by using, for example, a method of assigning the priority capable of using a system resource of the electronic device 10 (e.g., the bus 11, the processor 12, or the memory 13) to at least one of the applications 14d.

The API 14c is an interface for allowing the application 14d to control functions provided by the kernel 14a or the middleware 14b and may include, for example, at least one interface or function (e.g., commands) for a file control, a window control, an image processing, or a character control, for example.

The input/output interface 15 may serve as an interface capable of delivering commands or data, entered from, for example, a user or an external device to the other component(s) of the electronic device 10. Also, the input/output interface 15 may output commands or data received from the other component(s) of the electronic device 10 to the user or the external device.

The display 16 may include, for example, a liquid crystal display (LCD), a light emitting diode (LED) display, an organic light emitting diode (OLED) display, or a microelectromechanical systems (MEMS) display, or an electronic paper display. The display 16 displays various contents (e.g., text, image, video, icon, or symbol) to, for example, the user. The display 16 may include a touch screen, and may receive a touch input, a gesture input, a proximity input or a hovering input using, for example, an electronic pen or a part of the user's body.

The communication interface 17 may set, for example, a communication 21 or 23 between the electronic device 10 and an external electronic device (e.g., a first external electronic device 10a, a second external device 10b, or a server 20). For example, the communication interface 17 may communicate with the external device (e.g., the second external electronic device 10b or the server 20) by being connected with a network 21 through a wired or wireless communication.

The wireless communication may use at least one of, for example, LTE, LTE-A, CDMA, WCDMA, UMTS, WiBro and GSM, as a cellular communication protocol. The wired communication may use at least one of, for example, universal serial bus (USB), high definition multimedia interface (HDMI), recommended standard 232 (RS-232), and plain old telephone service (POTS). The network 21 may include a telecommunication network, for example, at least one of a computer network (e.g., local area network (LAN) or wide area network (WAN)), internet, and a telephone network.

Each of the first and second external electronic devices 10a and 10b may be a type of device that is the same as or different from the electronic device 10. According to one embodiment, the server 20 may include a group of one or more servers. According to various embodiments, all or some of the operations executed by the electronic device 10 may be executed by one or more other electronic devices (e.g., electronic devices 10a and 10b or the server 20). According to one embodiment, in a case where the electronic device 10 should perform a certain function or service automatically or by a request, the electronic device 10 may request some functions associated therewith from the other electronic devices (e.g., the electronic devices 10a and 10b or the server 20) instead of or in addition to executing the function or service by itself. The other electronic devices (e.g., the electronic devices 10a and 10b or the server 20) may execute the requested functions or additional functions, and may transmit the results to the electronic device 10. The electronic device 10 may provide the requested functions or services by processing the received results as they are or additionally. For this purpose, for example, a cloud computing technique, a distributed computing technique, or a client-server computing technique, may be used.

Embodiments disclosed herein are presented for the purpose of description and understanding of technical contents, but are not intended to limit the scope of the present disclosure. Accordingly, the scope of the present disclosure shall be interpreted as including all the modifications or other various embodiments based on the technical idea of the present disclosure.

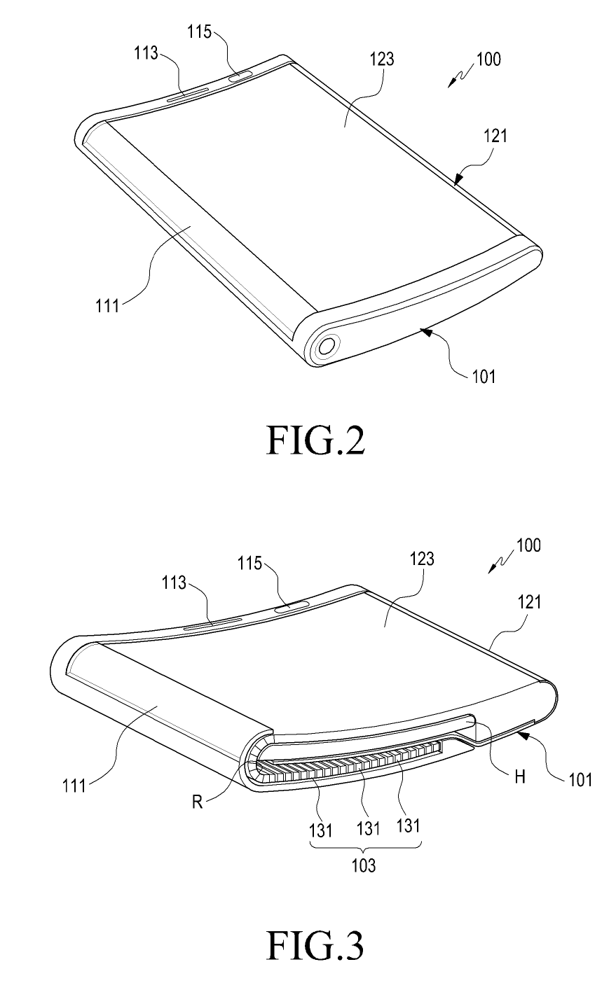

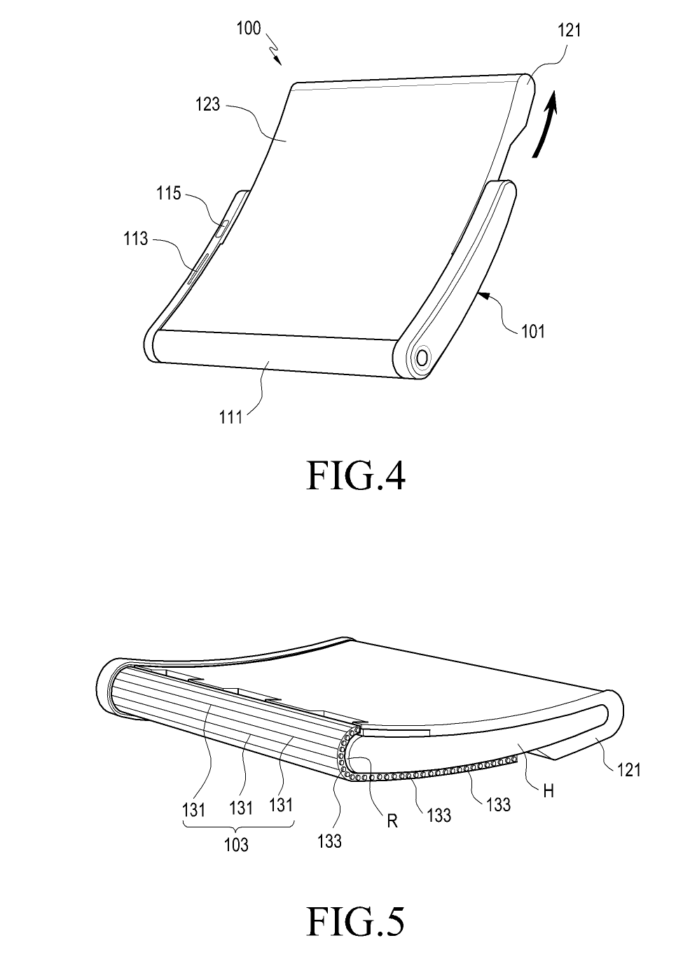

FIGS. 2, 3, 4, and 5 are various perspective views illustrating of an electronic device according to an embodiment of the present invention.

Referring to FIGS. 2, 3, 4, and 5, according to an embodiment of the present disclosure, an electronic device 100 (e.g., the electronic device 10) may include a main body 101, a flexible display element 123, and a support unit 103 (not shown). The flexible display element 123 and the support unit 103 may be partially accommodated in the main body 101. For example, the flexible display element 123 and the support unit 103 may be mounted to be movable in one direction on the main body 101, and may be selectively accommodated in the main body 101 as being moved on the main body 101.

One side surface of the main body 101 may be formed as a curved surface R that interconnects the front surface and the rear surface of the main body 101. A portion (hereinafter, referred to as a “first region”) of the flexible display element 123 and the support unit 103 may be moved along one side surface of the main body 101 (e.g., the curved surface R) between the front surface and the rear surface of the main body 101. For example, the first region such as, for example, a portion of the flexible display element 123, is disposed on the rear surface side of the main body 101 may be moved to the front surface of the main body 101 to be exposed. The main body 101 may accommodate a hardware assembly H including, for example, a circuit board and a battery pack. A curved window 111 may be mounted on a side surface of the main body 101, for example, the curved surface R. At least a part of the flexible display element 123 is positioned inside the curved window 111, and the curved window 111 may be transparent to transmit a screen output from the flexible display element 123. The main body 101 may be equipped with a receiver 113 or various sensors 115 proximate to an edge of the front surface thereof. The receiver 113 may output a sound during a voice call or multimedia mode, and the sensors 115 may include, for example, a proximity sensor or an illuminance sensor adjacent to the receiver 113. The sensors 115 may detect the environment of the electronic device 100 (e.g., temperature, humidity, illuminance, etc.).

The flexible display element 123 is supported by a slide unit 121 to be slidable on the main body 101. The slide unit 121 may be slidably coupled to the main body 101 and may protrude to the other side of the main body 101, for example, the side opposite to the curved surface R. According to the sliding movement of the slide unit 121, the flexible display element 123 is also movable on the main body 101. When the slide unit 121 protrudes to the other side of the main body 101, the flexible display element 123 may also be extended to the other side of the main body 101. The first region may be selectively disposed to face in the direction opposite to the other region of the flexible display element 123 when the first region is accommodated in the main body 101. For example, when the first region is disposed to face the rear surface of the main body 101, the first region is disposed within the main body 101 and the other portion of the flexible display element 123 may be disposed to face the front surface of the main body 101. When the first region is capable of outputting the screen to the outside, even when the first region is disposed within the main body 101, the electronic device 100 may output the screen to opposite sides of the main body 101.

The support unit 103 may be formed by support poles 131. The support poles 131 extend in a direction perpendicular to the sliding direction of the flexible display element 123 and may be arranged to be adjacent to each other. Opposite ends of each of the support poles 131 may be formed with guide projections 133, respectively. The support poles 131 may be deformed to correspond to the shape of the curved surface R and one end of the support unit 103 may be connected to the slide unit 121 to be movable on the main body 101 together with the slide unit 121. For example, the support unit 103 may be accommodated in the main body 101 on the rear surface side of the main body 101, and may be positioned on the front surface of the main body 101 by moving along the curved shape R. The support unit 103 is disposed to correspond to a portion (e.g., the first region) of the flexible display element 123, and may be coupled to face the inner surface of the flexible display element 123. For example, the support poles 131 may be attached to the inner surface of the flexible display element 123.

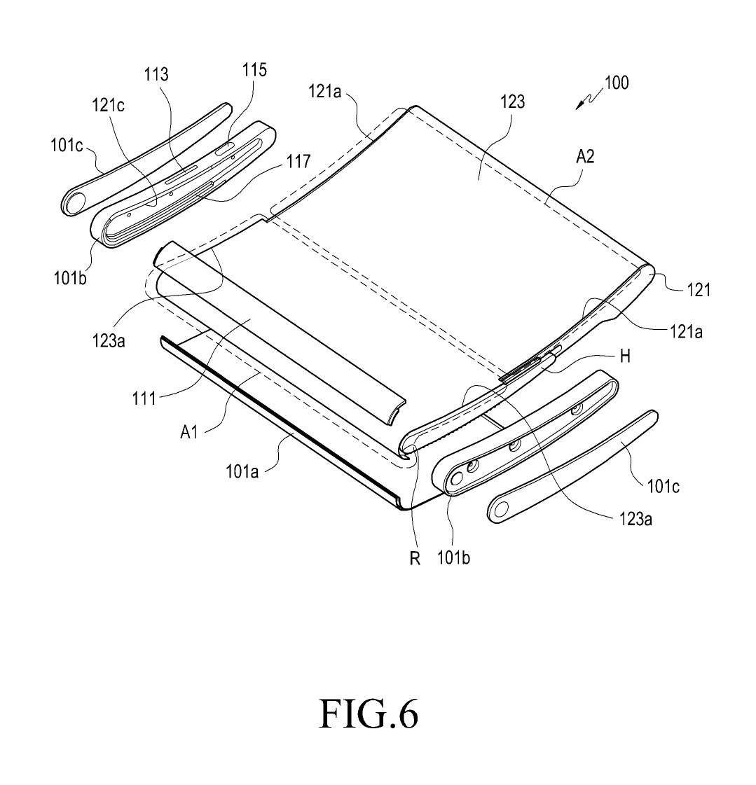

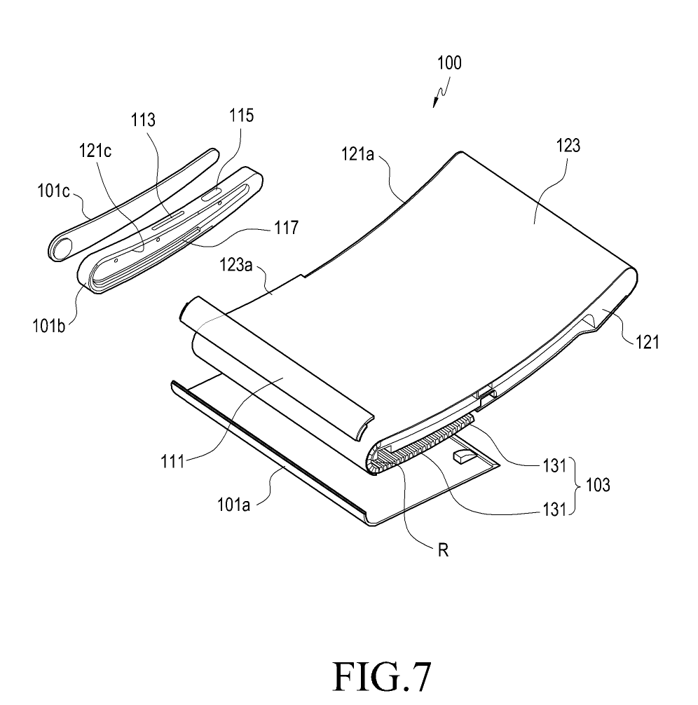

FIGS. 6, 7, and 8 are various exploded perspective views of an electronic device according to an embodiment of the present disclosure.

Referring to FIGS. 6, 7, and 8, the structure for guiding and supporting the movement of the flexible display element 123 in the electronic device 100 is illustrated in more detail.

The main body 101 may include a rear cover 101a that encloses the rear surface of the hardware assembly H, and cap members 101b are provided on the opposite ends of the rear cover 101a, respectively. The cap members 101b may be fixed to each of the hardware assembly H and the rear cover 101a. For example, the rear cover 101a may be coupled and fixed to the hardware assembly H through the cap members 101b. When the rear cover 101a and the hardware assembly H are coupled to each other, a space may be formed between the rear cover 101a and the hardware assembly H. A portion of the flexible display element 123 and the support unit 103 may be disposed within the space formed between the rear cover 101a and the hardware assembly H. For example, the portion of the flexible display element 123 and the support unit 103 may be moved on the main body 101 to be enclosed by the rear cover 101a.

Structures for guiding the movement of the support unit 103 and the slide unit 121 may be formed in the cap members 101b. For example, on the inner surfaces of the cap members 101b, guide recesses 117 may be formed, respectively. The guide recesses 117 may accommodate opposite ends of the support poles 131 so as to guide the movement of the support unit 103 on the main body 101. The guide projections 133 may move along the tracks formed by the guide recesses 117. The guide recesses 117 may extend from the rear surface side of the main body 101 to the front surface side of the main body 101 via the curved surface R side. For example, the guide recesses 117 may be formed as tracks that can sufficiently accommodate the movement range of the support unit 103.

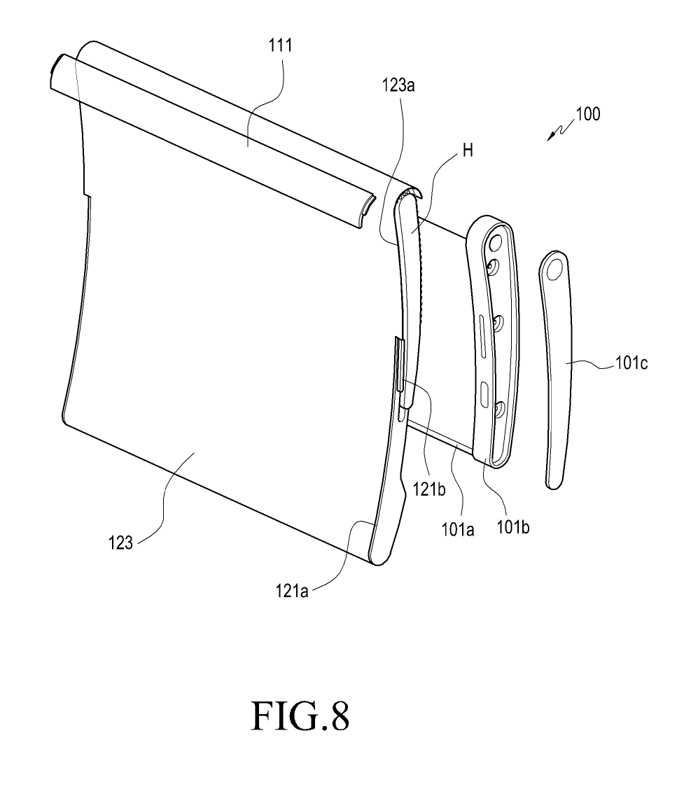

The cap members 101b may further include slide recesses 121c formed on the inner surfaces in addition to the guide recesses 117. The slide recesses 121c are provided to guide the sliding movement of the slide unit 121 and may be formed on the front surface side of the main body 101 in the inner surfaces of the cap members 10 lb. Referring to FIG. 8, slide projections 121b may be formed on the opposite ends of the slide unit 121, respectively. The slide projections 121b may be engaged in the slide recesses 121c, respectively, so as to guide the movement of the slide unit 121.

The main body 101 may further include decorative covers 101c that are attached to the outer surfaces of the cap members 101b, respectively. The decorative covers 101c may provide an ornamental effect to the exterior of the electronic device 100, and may reinforce the structure of the electronic device 100.

The curved window 111 may be fixed to the cap members 101b such that the curved window 111 contacts an edge of the rear cover 101a. The rear cover 101a may form a side of the main body 101 with the curved window 111.

The slide unit 121 may support portion A2 (hereinafter, referred to as a “second region”) of the flexible display element 123. Fixing ribs 121a may be formed in the opposite side edges of the front surfaces of the slide unit 121, respectively. The fixing ribs 121a may fix the opposite side edges of the second region A2, and the second region A2 may be wholly attached or integral to the slide unit 121 on the inner surface thereof. The top ends of the fixing ribs 121a may be formed to form a plane that is flush with the surface of the flexible display element 123. For example, the fixing ribs 121a may protrude from the front surface of the slide unit 121 by the thickness of the flexible display element 123.

The opposite side edges of the first region A1 of the flexible display element 123 may be extended beyond the opposite side edges of the second region A2. The portions 123a (hereinafter, referred to as “dummies”) extending beyond the opposite side edges of the second region A2 may have the same thickness and width as the fixing ribs 121a. In terms of the external appearance, the fixing ribs 121a may be utilized as a bezel structure for fixing the flexible display element 123. As the bezel structure is not formed in the first region A1, the first region A1 may be deformed to move along the curved shape R. The dummies 123a may form the same appearance as the fixing ribs 121a when the flexible display element 123 is extended (e.g., when the first region A1 is positioned on the front surface of the main body 101). For example, the flexible display element 123 may have the same color as the fixing ribs 121a in the dummies 123a or the surfaces of the dummies 123a may be coated with the same color as the fixing ribs 121a. By utilizing the dummies 123a as described above, the appearance of the portions, in which the fixing ribs 121a are formed, and the appearance of the portions, in which the fixing ribs 121a are not formed, may be consistent when the flexible display element 123 is extended on the main body 101.

When the flexible display element 123 is extended along a side direction of the main body 101, the slide unit 121 may support the second region A2 of the flexible display element 123. When the flexible display element 123 is extended in one side direction of the main body 101, the support unit 103 may be positioned on the front surface of the main body 101 to support the first region A1 of the flexible display element 123. Accordingly, before and after being extended in the side direction of the main body 101, the flexible display element 123 may be supported on each of the slide unit 121 and the support unit 103 so that the deformation of the flexible display element 123 may be suppressed. For example, if a touch screen function is incorporated in the flexible display element 123 and the user touches the flexible display element, the flatness of the flexible display element 123 can be maintained. By maintaining the flatness of the flexible display element 123, it is possible to prevent the distortion of the screen which may be caused due to deformation by an external force (e.g., the user's touch action) while the screen is being output.

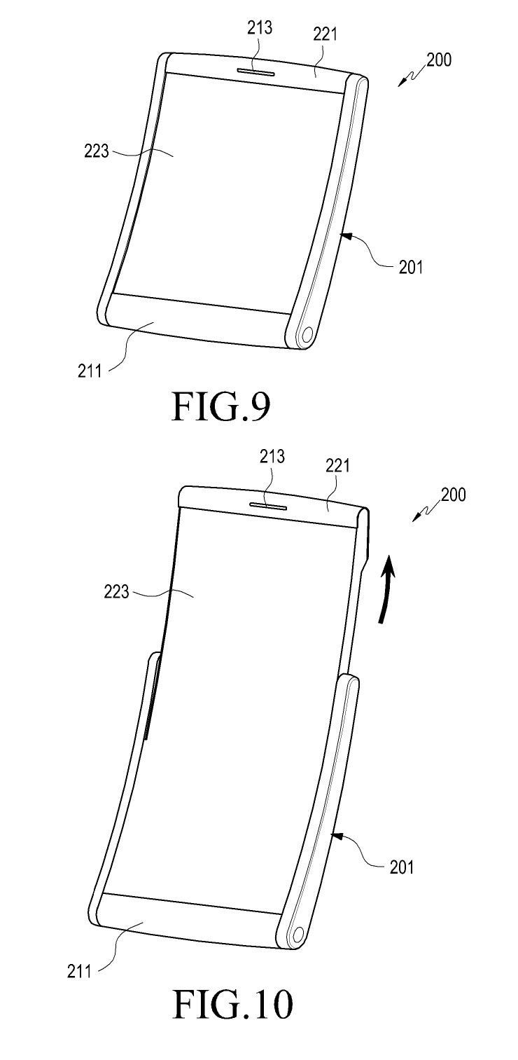

FIGS. 9 and 10 are various perspective views of an electronic device according to an embodiment of the present disclosure.

Referring to FIGS. 9 and 10, the electronic device 200 according to the present embodiment may have a structure in which the flexible display element 223 is extended in the longitudinal direction. The structures for supporting the flexible display element 223 and guiding the movement of, for example, the slide unit 221 may be implemented as described above. Therefore, detailed descriptions on substantially similar structures will be omitted.

The electronic device 200 includes a curved window 211 disposed in the lower end of the main body 201, and the flexible display element 223 may be extended in the direction of the upper end of the main body 201. The slide unit 221, which is slid on the main body 201 while supporting the flexible display element 223, may include the receiver 213 and various sensors that are disposed on the upper end. For example, at the voice call or multimedia media, the receiver 213 may output sound and the sensors may detect the surrounding illuminance or whether the user's body portion (e.g., the head) is proximate.

As described above, an electronic device 100 or 200 according to various embodiments of the present disclosure may allow the flexible display device 123 or 233 to be extended in the width direction (e.g., the horizontal direction) or in the longitudinal direction (e.g., the vertical direction), depending on the implementation of electronic device 100 or 200. In addition, when the flexible display element 123 or 223 is extended, the slide unit 121 or 221 and the support unit 103 may support the entire region of the flexible display element 123 or 223 to prevent distortion of the screen due to the deformation of the flexible display element 123 or 223.

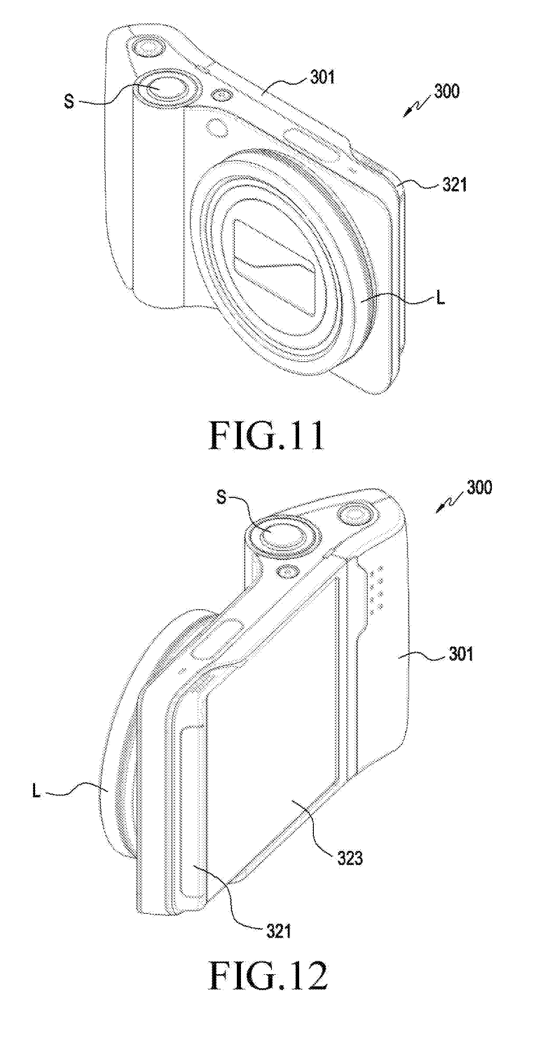

FIGS. 11, 12, 13, 14, and 15 are various perspective views illustrating an electronic device according to an embodiment of the present disclosure.

Referring to FIGS. 11, 12, 13, 14, and 15, the electronic device 300 may be implemented as a digital camera. The electronic device 300 may include a lens unit L disposed on the front surface of a main body 301, and a shutter button S disposed on one side surface (e.g., the top surface) of the main body 301. On the rear surface of the main body 301, a slide unit 321 may be disposed to extend and withdraw from the other side surface of the main body 301. On the slide unit 321, a flexible display element 323 may be disposed to be slid in relation to the main body 301 together with the slide unit 321. For example, while being slid on the main body 301, the flexible display element 323 may be extended from a side of the main body 301. The structures slidably fix the slide unit 321 to the main body 301, thereby guiding the movement of the flexible display element 323 and supporting the flexible display element 323.

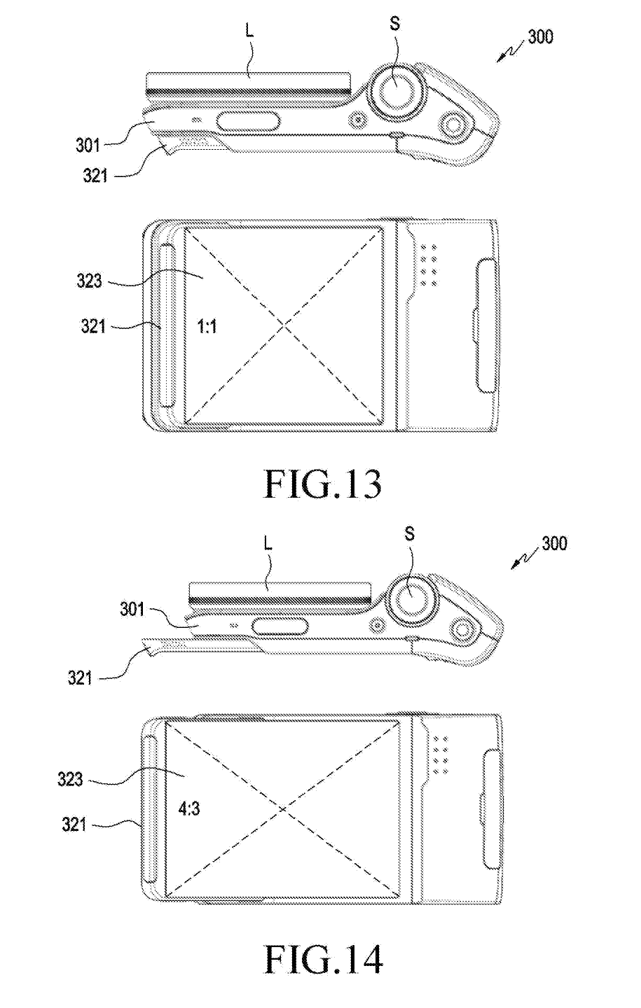

Referring to FIGS. 13, 14, and 15, the flexible display element 323 is extended from a side of the main body 301 according to an embodiment of the present disclosure.

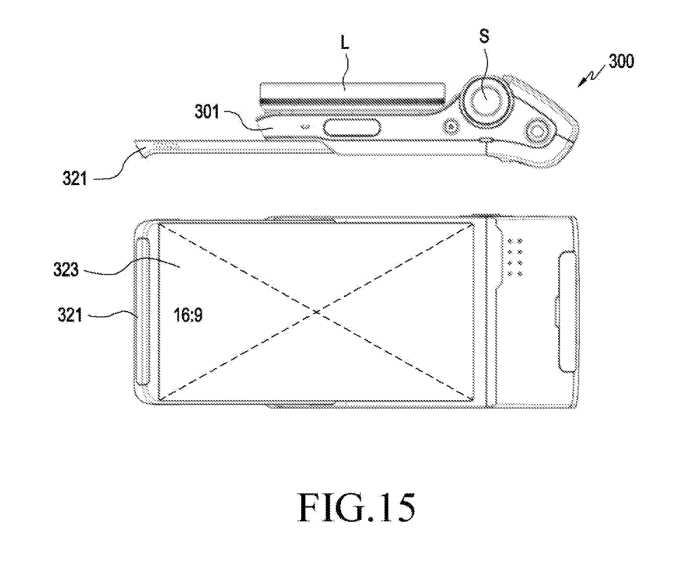

Referring to FIG. 13, the slide unit 321 is completely disposed within the main body 301, the flexible display element 323 may output a screen having an aspect ratio of 1:1. Referring to FIGS. 14 and 15, after sliding of the slide unit 321, the flexible display element 323 may output a screen having an aspect ratio of 4:3 or 16:9 based on the amount of movement. The electronic device 300 may set the photographing mode based on the amount that the flexible display element 323 is extended from the main body 301 (e.g., the aspect ratio of the output screen). For example, when the flexible display element 323 is positioned to have an aspect ratio of 1:1, the electronic device 300 may perform functions of retrieving information concerning, for example, neighboring buildings or shopping centers, and outputting the information to the flexible display element 323. When the flexible display element 323 is positioned with an aspect ratio of 4:3, the electronic device 300 may be set to a photographing mode. When the flexible display element 323 is positioned with an aspect ratio of 16:9, the electronic device 300 may be set to a video image photographing mode.

An electronic device, according to various embodiments of the present disclosure, may include a main body, a flexible display element that is mounted to be movable in one direction on the main body, and a support unit disposed that faces one surface of the flexible display element and moves in one direction on the main body. A portion (hereinafter, referred to as a “first region”) of the flexible display element may be selectively accommodated in the main body together with the support unit while moving on the main body.

According to various embodiments, the first region may be disposed to be directed to a direction opposite to another portion of the flexible display element when the first region is disposed within the main body.

The electronic device as described above may further include a slide unit that is coupled to the main body to be slid in one direction, and the second region may be fixed to the slide unit.

According to various embodiments, the electronic device described above may further include slide recesses that extend in a direction, in which the slide unit moves, on opposite inner surfaces of the main body and at least one slide projection that is formed on each side surface of the slide unit. The slide projections may be engaged in the slide recesses to guide the movement of the slide unit.

According to various embodiments, the electronic device described above may further include fixing ribs that are formed in opposite side edges of the slide unit, respectively, and opposite side edges of the second region may be fixed adjacent to the fixing ribs, respectively.

According to various embodiments, wherein the opposite side edges of the first region are extended beyond the opposite side edges of the second region and are arranged along the moving direction of the slide unit together with the fixing ribs.

According to various embodiments, the electronic device disclosed above may further include a receiver that is provided in one end of the slide unit to be moved in relation to the main body together with the slide unit.

According to various embodiments, the support unit may include a plurality of support poles that extend in a direction perpendicular to the moving direction of the flexible display element, and the support poles may be arranged to be adjacent to each other along the moving direction of the flexible display element within the first region.

According to various embodiments, the electronic device described above may further include guide projections that are formed on the opposite ends of each of the support poles, respectively, and guide recesses that are formed on opposite inner surfaces of the main body, respectively. The guide projections may be engaged in the guide recesses so as to guide the movement of the support poles.

According to various embodiments, one side surface of the main body may be formed as a curved surface that connects a front surface and a rear surface of the main body, and the support poles may move along the curved surface between the front surface and the rear surface of the main body together with the first region.

According to various embodiments, the electronic device may further include a curved window that is mounted on one side surface of the main body, and at least a part of the flexible display element may be positioned inside the curved window.

According to various embodiments, the electronic device may further include at least one receiver that is provided on the main body.

In addition, an electronic device, according to various embodiments of the present disclosure, may include: a main body, a slide unit that is coupled to the main body and is slid in one direction, a support unit that is provided in one end of the slide unit to move on the main body together with the slide unit, and a flexible display element fixed to the slide unit. As the slide unit moves, a portion of the flexible display element may be selectively disposed within the main body together with the support unit.

According to various embodiments, wherein one side surface of the main body may be formed as a curved surface. As the slide unit is slid on the main body, the flexible display element may be extended toward the other side of the main body.

According to various embodiments, one side surface of the main body may be formed as a curved surface, and the flexible display element may move, together with the support unit, from the front surface of the main body to the rear surface side of the main body along the curved surface.

According to various embodiments, the electronic device described above may further include a curved window that is mounted on the one side surface of the main body.

According to various embodiments, at least a part of the flexible display element may be positioned inside the curved window.

According to various embodiments, the support unit may include a plurality of support poles that extend in a direction perpendicular to the moving direction of the slide unit, and the support poles may be arranged to be adjacent to each other along the moving direction of the slide unit from one end of the slide unit.

According to various embodiments, a portion of the flexible display element may be supported on the support poles, and another portion is fixed to the slide unit.

While the present disclosure has been shown and described with reference to various embodiments thereof, it will be understood by those skilled in the art that various changes in form and details may be made therein without departing from the spirit and scope of the present disclosure as defined by the appended claims.

What is claimed is:

1. An electronic device comprising:
a main body;
a flexible display mounted to be movable in a first direction on the main body; and
a support unit disposed on the main body that faces a surface of the flexible display and moves in the direction on the main body,
wherein a first region of the flexible display is selectively disposed within the main body together with the support unit while moving on the main body.

2. The electronic device of claim 1, wherein, when the first region of the flexible display is selectively disposed within the main body, the first region of the flexible display faces a direction opposite of a second region of the flexible display.

3. The electronic device of claim 2, further comprising:
a slide unit that is coupled to the main body to be slid in the first direction,
wherein the second region of the flexible display is fixed to the slide unit.

4. The electronic device of claim 3, further including:
slide recesses disposed on opposite inner surfaces of the main body; and
a slide projection formed on each side surface of the slide unit,
wherein the slide projections are engaged in the slide recesses to guide the movement of the slide unit in the first direction.

5. The electronic device of claim 3, further comprising:
fixing ribs that are formed in opposite side edges of the slide unit, respectively,
wherein opposite side edges of the second region of the flexible display are fixed adjacent to the fixing ribs.

6. The electronic device of claim 5, wherein the opposite side edges of the first region of the flexible display are extended beyond the opposite side edges of the second region of the flexible display and are arranged along the first direction of the slide unit with the fixing ribs.

7. The electronic device of claim 3, further comprising:
a receiver that is disposed on one end of the slide unit to be moved in relation to the main body together with the slide unit.

8. The electronic device of claim 1, wherein the support unit includes a plurality of support poles that extend in a direction perpendicular to the first direction, and
the support poles are arranged to be adjacent to each other along the first direction of the flexible display within the first region.

9. The electronic device of claim 8, further comprising:
guide projections formed on the opposite ends of each of the support poles; and
guide recesses formed on opposite inner surfaces of the main body,
wherein the guide projections are engaged in the guide recesses to guide the movement of the support poles.

10. The electronic device of claim 8, wherein a side surface of the main body is formed as a curved surface that connects a front surface and a rear surface of the main body, and
the support poles move along the curved surface between the front surface and the rear surface of the main body together with the first region of the flexible display.

11. The electronic device of claim 10, further comprising:
a curved window that is fixed to the side surface of the main body,
wherein a part of the first region of the flexible display is positioned inside the curved window.

12. The electronic device of claim 11, wherein the curved window exposes a portion of the first region of the flexible display to be visible.

13. The electronic device of claim 1, further comprising:
at least one receiver on the main body.

14. An electronic device comprising,
a main body;
a slide unit coupled to the main body and to be displaced in a movement direction;
a support unit provided in an end of the slide unit to move on the main body together with the slide unit; and
a flexible display fixed to the slide unit,
wherein as the slide unit moves, a first portion of the flexible display is selectively disposed within the main body together with the support unit.

15. The electronic device of claim 14, wherein a side surface of the main body is formed as a curved surface, and
as the slide unit is displaced on the main body, a second portion of the flexible display changes based on the displacement of the slide unit.

16. The electronic device of claim 14, wherein the side surface of the main body is formed as a curved surface, and
the flexible display and the support unit are displaced from the front surface of the main body to the rear surface side of the main body along the curved surface.

17. The electronic device of claim 15, further comprising:
a curved window mounted on the side surface of the main body.

18. The electronic device of claim 17, wherein a part of the flexible display is positioned inside the curved window to be visible.

19. The electronic device of claim 14, wherein the support unit includes a plurality of support poles that extend in a direction perpendicular to the movement direction, and
the support poles are arranged to be adjacent to each other along the movement direction of the slide unit.

20. The electronic device of claim 19, wherein a first region of the flexible display is supported on the support poles, and a second region of the flexible display is fixed to the slide unit.
